(19) United States
(12) Patent Application Publication
(10) Pub. No.: US 2021/0296241 A1
(43) Pub. Date: Sep. 23, 2021

(54) MICROELECTRONIC PACKAGE WITH REDUCED THROUGH-SUBSTRATE ROUTING

(71) Applicant: Intel Corporation, Santa Clara, CA (US)

(72) Inventors: Arghya Sain, Chandler, AZ (US); Lesley A. Polka Wood, Chandler, AZ (US); Russell K. Mortensen, Chandler, AZ (US)

(73) Assignee: Intel Corporation, Santa Clara, CA (US)

(21) Appl. No.: 16/825,261

(22) Filed: Mar. 20, 2020

(51) Int. Cl. H01L 23/538; H01L 23/498

(52) U.S. Cl. CPC H01L 23/5381; H01L 23/5389; H01L 23/49816; H01L 23/5386

(57) ABSTRACT

Embodiments may relate to a microelectronic package that includes an active die at a first side of the substrate and an interconnect at a second side of the substrate. A high-speed input/output (HSIO) die may also be coupled with the first side of substrate. The HSIO die may be coupled with the active die by a bridge. Other embodiments may be described or claimed.

### BACKGROUND

The demand for data and bandwidth in electronic devices is increasing. The demands, in turn, are pushing high-speed input/output (HSIO) signals higher into speeds such as 56 gigabits per second (Gbps), 112 Gbps, 224 Gbps, etc. The demands are also creating a demand for increased lane counts.

### BRIEF DESCRIPTION OF THE DRAWINGS

FIGS. 1a and 1b depict simplified top-down and bottom-up, respectively, views of an example microelectronic package with a reduced through-substrate signal routing pathway, in accordance with various embodiments.

FIG. 2 depicts a simplified cross-sectional view of an example microelectronic package with a reduced through-substrate signal routing pathway, in accordance with various embodiments.

FIG. 3 depicts a simplified cross-sectional view of an example microelectronic package with a reduced through-substrate signal routing pathway, in accordance with various embodiments.

FIG. 4 depicts a simplified cross-sectional view of an example microelectronic package with a reduced through-substrate signal routing pathway, in accordance with various embodiments.

FIG. 5 depicts a simplified cross-sectional view of an example microelectronic package with a reduced through-substrate signal routing pathway, in accordance with various embodiments.

FIG. 6 depicts a simplified cross-sectional view of an example microelectronic package with a reduced through-substrate signal routing pathway, in accordance with various embodiments.

FIG. 7 depicts a simplified top-down view of an example microelectronic package with a reduced through-substrate signal routing pathway, in accordance with various embodiments.

FIG. 8 is a side, cross-sectional view of an integrated circuit (IC) device assembly that may include a microelectronic package with a reduced through-substrate signal routing pathway, in accordance with various embodiments.

FIG. 9 is a block diagram of an example electrical device that may include a microelectronic package with a reduced through-substrate signal routing pathway, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature [[formed/deposited/disposed/etc.]] on a second feature,” may mean that the first feature is formed/deposited/disposed/etc. over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As noted, the demand for data and bandwidth may be increasing, which may push HSIO speeds higher and increase lane counts. The higher bandwidth and higher lane count may lead to microelectronic packages with an increased form factor, and the need for higher input/output (I/O) interconnects per millimeter (mm). This increase may result in longer on-package route length, which may result in increased signal loss. Trying to increase the number of I/Os per mm may lead to tighter trace width (TW)/trace spacing (TS), which may also increase loss. The combination of increase in route length along with narrower TW/TS may result in significantly higher loss on a microelectronic package, which may in turn reduce the loss budget available to the overall platform of which the microelectronic package is a part. Legacy microelectronic packages may use wider TW/TS to meet the loss budget, but the resultant reduction in I/Os per mm may require compensation in the form of more package layers, which may increase the z-height, cost, or manufacturing difficulty of the microelectronic package.

Embodiments herein may address one or more of the above-described difficulties relating to package loss. In various embodiments, HSIO chips may be placed on the package close to their corresponding ball grid array (BGA) interconnects, which may minimize on-package trace route length. This lower on-package route length may lower the overall loss from the HSIO die to a BGA interconnect, which may allow for the use of traces with a narrower TW/TS. As a result, the microelectronic packages may meet the higher I/O per mm design goals while staying within or below a desirable package loss budget. The HSIO chips may be connected to the main die via relatively narrow traces (e.g., traces with a TW/TS values of approximately 5 micrometers (“microns”)/5 microns or less), a passive bridge, an active bridge, two or more bridges with a chip between, etc. The chip may be, for example, a repeater (which may also be referred to as, or be replaced by, a “retimer”), a serializer/deserializer (SERDES), or some other type of die. The SERDES may be, for example a relatively low-speed SERDES such as a peripheral component interconnect express (PCIe) generation 3 (Gen3) 8 Gbps SERDES, or some other type of SERDES.

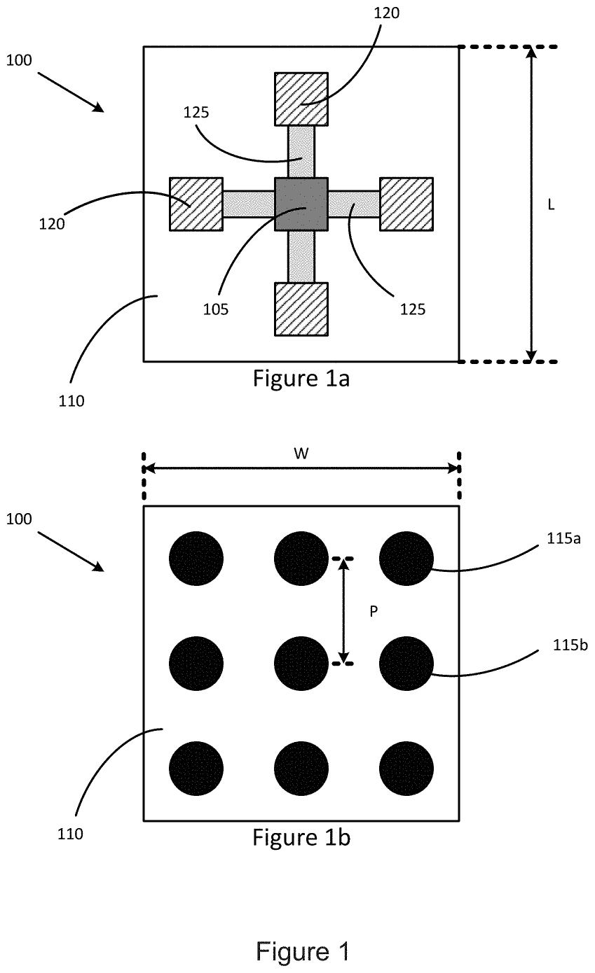

FIGS. 1a and 1b (collectively, “FIG. 1”) depict simplified top-down and bottom-up, respectively, views of an example microelectronic package 100 with a reduced through-substrate signal routing pathway, in accordance with various embodiments. It will be understood that the embodiment of FIG. 1 is intended as an example embodiment that is not necessarily to scale. Rather, certain elements are depicted for the sake of illustration of concepts, but relative sizes of elements, the shapes of the various elements, or the number of elements should not be viewed as limiting unless otherwise explicitly stated. It will also be understood that each and every element of FIG. 1 may not be explicitly numbered in the Figure for the sake of lack of clutter of the Figure. However, elements that share similar characteristics (e.g., are the same shape and shading, etc.) may be viewed as being similar to one another.

More generally, it will be recognized that FIGS. 1-7 are intended as highly simplified example Figures of various embodiments or concepts of the present disclosure. Various of the depicted microelectronic packages may include additional active elements (e.g., processors, memory, logic, etc.), passive elements (e.g., capacitors, resistors, inductors, etc.), or conductive elements (e.g., pads, striplines, microstrips, vias, traces, etc.) that are not depicted in the Figures for the sake of lack of clutter of the Figures.

The microelectronic package 100 may include a die 105 coupled with a package substrate 110. The die 105 may be or include, for example, a processor such as a central processing unit (CPU), a general processing unit (GPU), a core of a distributed processor, or some other type of processor. Alternatively, the die 105 may be include a memory such as a double data rate (DDR) memory, a nonvolatile memory (NVM), a volatile memory, a read-only memory (ROM), or some other type of memory or die. In some embodiments the die 105 may be or include a radio frequency (RF) chip or RF circuitry that is configured to generate, process, transmit, or receive a wireless signal such as a third generation (3G), a fourth generation (4G), a fifth generation (5G), a Wi-Fi, or some other type of wireless signal. In some embodiments the die 105 may include one or more passive components such as capacitors, resistors, etc. The various active or passive components may be positioned within, partially within, or on the surface of the die 105.

The package substrate 110 may be, for example, considered to be a cored or coreless substrate. The package substrate 110 may include one or more layers of a dielectric material which may be organic or inorganic. The package substrate 110 may further include one or more conductive elements such as vias, pads, traces, microstrips, striplines, etc. The conductive elements may be internal to, or on the surface of, the package substrate. Generally, the conductive elements may allow for the routing of signals through the package substrate 110, or between elements that are coupled to the package substrate 110. In some embodiments the package substrate 110 may be, for example, a printed circuit board (PCB), an interposer, a motherboard, or some other type of substrate. In some embodiments, the package substrate 110 may have a length L and a width W of approximately 60 mm by 60 mm. However, it will be understood that in other embodiments the package substrate 110 may have a larger or smaller length L or width W. The specific length or width of the package substrate 110 may be based on factors such as manufacturing considerations, the use case to which the microelectronic package 100 may be put, materials used, etc.

The package substrate may include or be coupled with one or more interconnects such as interconnects 115. The interconnects 115 may be, for example, solder bumps that are formed of a material such as tin, silver, copper, etc. If solder bumps are used for the interconnects 115, then the solder bumps may be elements of a BGA as shown in FIG. 1. In other embodiments, the interconnects 115 may be pins of a pin grid array (PGA), elements of a solder grid array (SGA), elements of a land grid array (LGA), or some other type of interconnect. Generally, the interconnects 115 may be to physically or communicatively couple the microelectronic package 100 with a PCB of an electronic device of which the microelectronic package 100 is a part. For example, one or more of the interconnects 115 may physically couple with, and allow electrical signals to pass between, pads of the microelectronic package 100 and pads of the PCB. In other embodiments, the interconnects 115 may physically couple the microelectronic package 100 to the PCB, but the interconnects 115 may not communicatively couple the microelectronic package 100 and the PCB. In some embodiments, the interconnects 115 may have a pitch P, which may represent a distance from the center of one interconnect 115 to the center of another interconnect 115. In some embodiments, the pitch P may be less than 5 mm, and more specifically in some embodiments the pitch P may be approximately 1 mm or less, as discussed above.

The microelectronic package 100 may further include a number of HSIO dies 120 coupled with the package substrate 110. The HSIO dies 120 may be coupled with the active die 105 by a number of bridges 125. As will be described in further embodiments below, the bridge 125 may be a passive bridge, an active bridge, or some other type of bridge. It will be understood, however, that in some embodiments, one or more of the bridges 125 may be replaced with a different type of communicative coupling between the HSIO die 120 and the active die 105. For example, one or more of the bridges 125 may be replaced by a number of signal lines with a TW/TS space of 5 microns/5 microns or less. In some embodiments, the microelectronic package may include an additional chip such as a SERDES die/repeater/re-timer/etc. positioned in the signal path between the active die 105 and an HSIO die 120.

Generally, the HSIO die 120 may be a die with active logic that is configured to receive a signal from the active die 105, alter the signal in accordance with a high-speed communication protocol, and then output the high-speed signal to one of the interconnects 115 by way of a through-substrate routing path as will be explained in greater detail with respect to other Figures. Similarly, the HSIO die 120 may receive one or more signals that are in accordance with a high-speed protocol and convert the signal to a format that is appropriate for the active die 105. The HSIO die 120 may then output that converted signal to the active die 105 by way of one or more bridges 125 or some other signal path that will be explained in greater detail below.

The bridges 125 may be formed of a material such as silicon or some other material that facilitates communication between two elements of the microelectronic package 100. In some embodiments, the bridges 125 may facilitate optical communication between, for example, the active die 105 and an HSIO die 120. In these embodiments the active die 105 and the HSIO die 120 may be configured to send or receive one or more optical signals through the bridge 125. In other embodiments, the bridge 125 may be another type of bridge 125 that facilitates communication between two elements of the microelectronic package 100. For example, the bridge 125 may be an electrical bridge that facilitates electrical communication between two elements of the microelectronic package 100.

As may be seen in FIG. 1, and particularly FIG. 1a, the microelectronic package may include HSIO dies 120 on a plurality of sides of the active die 105. Specifically, the microelectronic package 100 of FIG. 1 may include HSIO dies 120 on four sides of the active die 105. Such a configuration may be desirable because, as will be explained in further detail with respect to other embodiments, it may move the HSIO dies 120 closer to the interconnects 115 to which they are communicatively coupled, thereby reducing the length of the through-substrate routing path. The path reduction may reduce or otherwise mitigate losses of the microelectronic package. However, moving the HSIO dies 120 closer to the interconnects 115 may increase the length of the signal path between the active die and the HSIO dies 120. Moving the active die 105 closer to a given HSIO die 120 to mitigate this signal path length increase may be ineffective because it may have the effect of lengthening the signal path between the active die 105 and another of the HSIO dies 120. Therefore, the use of one or more bridges and chips (e.g., a SERDES or repeater) or an active bridge such as an embedded multi-die interconnect bridge (EMIB) may be desirable to decrease the amount of loss that the signal sees in the connection between the active die 105 and an HSIO die 120.

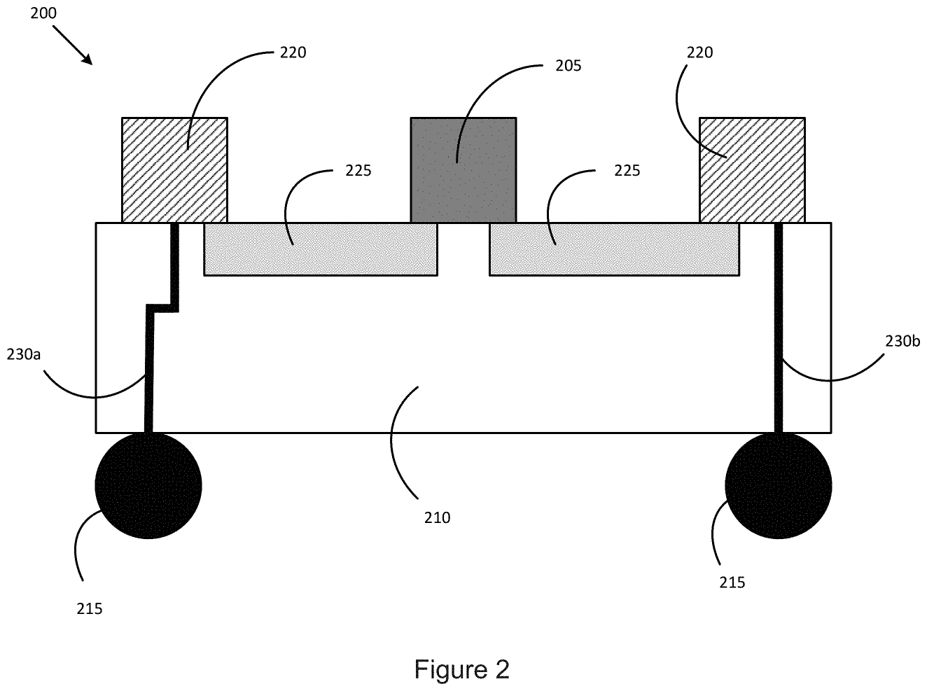

FIG. 2 depicts a simplified cross-sectional view of an example microelectronic package 200 with a reduced through-substrate signal routing pathway, in accordance with various embodiments. Generally, FIG. 2 may be considered to be a microelectronic package that is similar to, and shares one or more characteristics with, microelectronic package 100. Specifically, the microelectronic package 200 may include an active die 205, a plurality of HSIO dies 220, bridges 225, package substrate 210, and interconnects 215 which may be respectively similar to, and share one or more characteristics with, active die 105, HSIO dies 120, bridges 125, package substrate 110, and interconnects 115.

The microelectronic package 200 may further include a number of through-substrate routings paths 230a and 230b (collectively, “through-substrate routing paths 230”) that communicatively couple an HSIO die 220 and an interconnect 215. The through-substrate routing paths 230 may be formed of a number of conductive elements such as traces, pads, striplines, microstrips, vias, etc. The through-substrate routing path 230a may be depicted as including two vias and a trace, whereas the through-substrate routing path 230b may be depicted as being formed of a single through-substrate via. However, it will be understood that these depictions are highly simplified and, in real-world embodiments, the through-substrate routing paths 230 may include a number of conductive elements positioned between, in, or through, various layers of the package substrate 210. However, because the HSIO dies 220 are positioned closer to the interconnects 215, it will be noted that the communicative coupling (e.g., the through-substrate routing paths 230) may be significantly shortened in comparison to legacy embodiments where the HSIO dies 220 were closer to the active die 205 and further from the interconnects 215. Specifically, the communicative coupling between the HSIO dies 220 and the interconnects 215 may have a length on the order of approximately 10 mm or less. By shortening the length of the communicative coupling between the HSIO dies 220 and the interconnects 215, the signal loss between the HSIO dies 220 and the interconnects 215 may be significantly reduced in comparison to the signal loss experienced in legacy microelectronic packages.

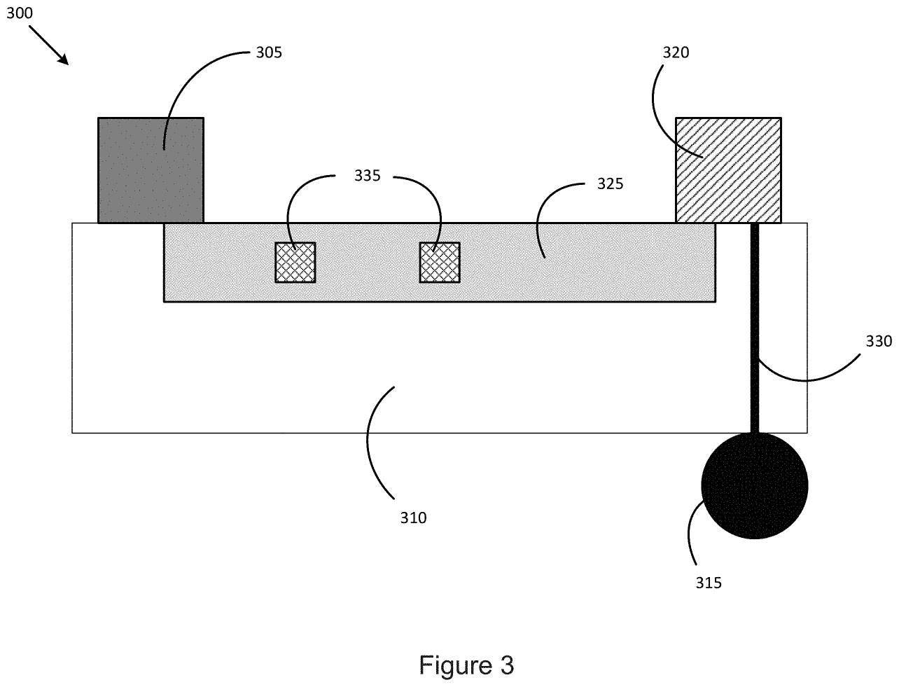

FIGS. 3-6 depict alternative configurations of an example microelectronic package with one or more structures that may assist with mitigating loss between the active die and the HSIO die. Generally, the embodiments of FIGS. 3-6 may be described with respect to elements of FIG. 2 for the sake of consistent description, however it will be understood that elements of FIGS. 3-6 may include elements similar to those of each other, similar to those of FIG. 1, etc.

As noted, moving the HSIO die closer to an interconnect may mitigate loss between the HSIO die and the interconnect, but may increase loss in the signal path between the active die and the HSIO die. Therefore, it may be desirable to include one or more structures which may reduce or otherwise mitigate the loss between the active die and the HSIO die. It will be understood that the Figures only depict a single signal path between an active die and an HSIO die, however in real-world embodiments the depicted microelectronic packages may include a plurality of signal paths and a plurality of HSIO dies as depicted, for example, in FIG. 1 or 2. The microelectronic packages may have an identical signal path between the active die and each HSIO die (e.g., all of the signal paths may include an active bridge) while in other embodiments the microelectronic packages may include a number of different signal paths (e.g., one signal path that includes an active bridge and another signal path that includes a repeater). It will also be understood that various of the embodiments herein may be combined (e.g., a signal path may include both an active bridge and a repeater). Other variations may be present in other embodiments.

Turning to a specific embodiment, FIG. 3 depicts a simplified cross-sectional view of an example microelectronic package 300 with a reduced through-substrate signal routing pathway, in accordance with various embodiments. The microelectronic package 300 may include an active die 305, a package substrate 310, an HSIO die 320, an interconnect 315, and a through-substrate routing path 330 which may be respectively similar to, and share one or more characteristics with, active die 205, package substrate 210, HSIO die 220, interconnect 215, and through-substrate routing path 230.

The microelectronic package 300 may further include an active bridge 325. In some embodiments, the active bridge 325 may be, or be referred to, as an EMIB. The active bridge may be generally similar to bridges 125 or 225 in that it may be composed of silicon or a like material and allow communication between the active die 305 and the HSIO die 320. In some embodiments, the active bridge 325 may allow for or facilitate optical coupling or communication between the active die 305 and the HSIO die 320, whereas in other embodiments the active bridge 325 may allow for or facilitate electrical coupling or communication between the active die 305 and the HSIO die 320.

The active bridge 325 may further include one or more active elements 335 positioned therein. The active elements 335 may be or may include circuitry or logic configured to alter a signal passing through the active bridge 325. Such circuitry may include repeaters, amplifiers, processors, etc. Generally, the active elements 335 may be configured to reduce or otherwise mitigate the signal loss experienced by a signal traversing the signal path between the active die 305 and the HSIO die 320.

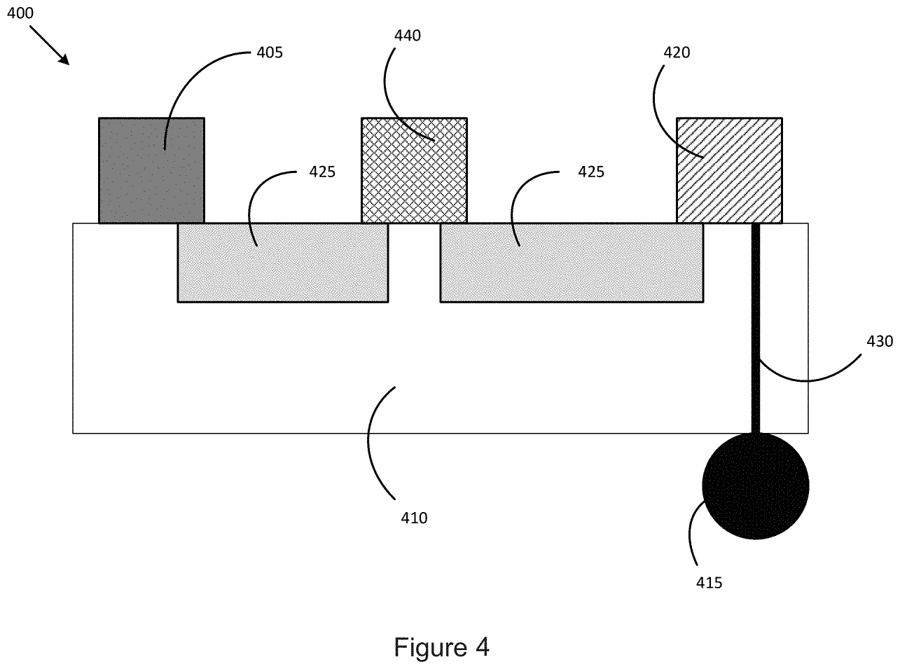

FIG. 4 depicts a simplified cross-sectional view of an example microelectronic package 400 with a reduced through-substrate signal routing pathway, in accordance with various embodiments. The microelectronic package 400 may include an active die 405, a package substrate 410, an HSIO die 420, an interconnect 415, and a through-substrate routing path 430 which may be respectively similar to, and share one or more characteristics with, active die 205, package substrate 210, HSIO die 220, interconnect 215, and through-substrate routing path 230.

The microelectronic package 400 may further include a second active die 440, either coupled to (as shown), positioned within, or partially positioned within the package substrate 410. Generally, the second active die 440 may be positioned in the signal path between the active die 405 and the HSIO die 420 as shown. In the specific embodiment of FIG. 4, the second active die 440 may be coupled to the active die 405 by a first bridge 425, and coupled to the HSIO die 420 by a second bridge 425 (both of which may be similar to, and share one or more characteristics with, bridge 225).

Similarly to the active bridge 325, the second active die 440 may be or include circuitry configured to mitigate signal loss of the signal in the signal path between the active die 405 and the HSIO die 420. For example, the second active die 440 may be a repeater, a SERDES die, or some other type of active die. As described above, the SERDES may be a relatively low-speed SERDES such as a PCIe Gen3 8 Gbps SERDES, or some other type of SERDES die.

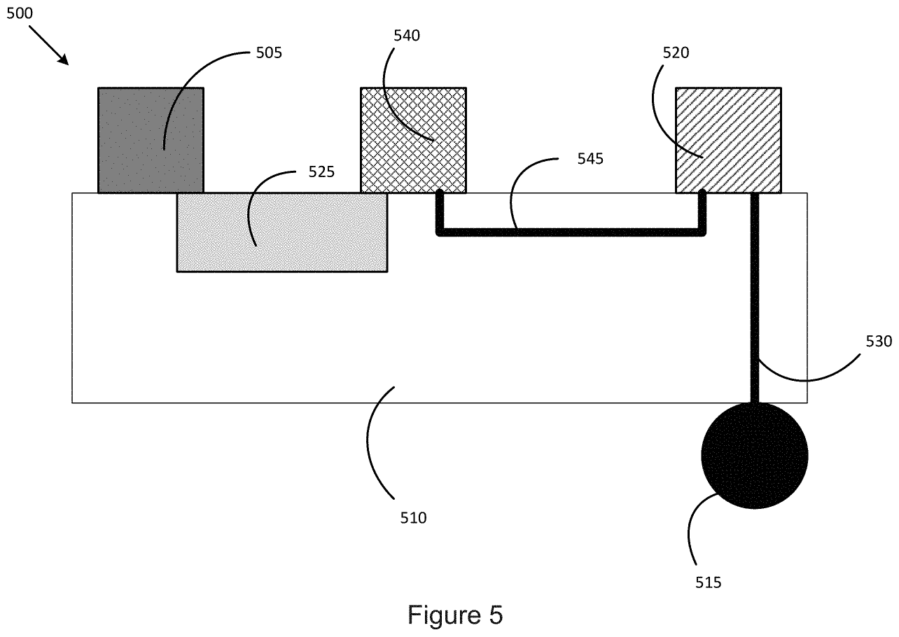

FIG. 5 depicts a simplified cross-sectional view of an example microelectronic package 500 with a reduced through-substrate signal routing pathway, in accordance with various embodiments. The microelectronic package 500 may include an active die 505, a package substrate 510, an HSIO die 520, an interconnect 515, a through-substrate routing path 530, a second active die 540, and a bridge 525 which may be respectively similar to, and share one or more characteristics with, active die 205, package substrate 210, HSIO die 220, interconnect 215, through-substrate routing path 230, second active die 440, and bridge 225.

The microelectronic package 500 may further include high-density package (HDP) routing 545 in the signal path between the active die 505 and the HSIO die 520. The HDP routing 545 may include, for example, one or more traces or other conductive elements that communicatively couple two elements of the microelectronic package. In some embodiments, the traces of the HDP routing 545 may have a TW/TS of approximately 5/5 (e.g., a TW value of approximately 5 microns and a TS value of approximately 5 microns) while in other embodiments the HDP routing 545 may have a TW/TS of less than 5/5. For example, in some embodiments the HDP routing 545 may have a TW/TS of approximately 2/2.

In the embodiment of FIG. 5, the HDP routing 545 may communicatively couple the active die 540 and the HSIO die 520, while the bridge 525 may communicatively couple the active dies 505 and 540. However, in other embodiments, the HDP routing 545 may additionally or alternatively communicatively couple the active dies 505 and 540. For example, the HDP routing 545 may communicatively couple the active dies 505/540 together, and other HDP routing 545 may communicatively couple the active die 540 with the HSIO die 520. In other embodiments, the HDP routing 545 may communicatively couple the active dies 505/540 while the bridge 525 communicatively couples the active die 540 and the HSIO die 520. Other variations may be present in other embodiments.

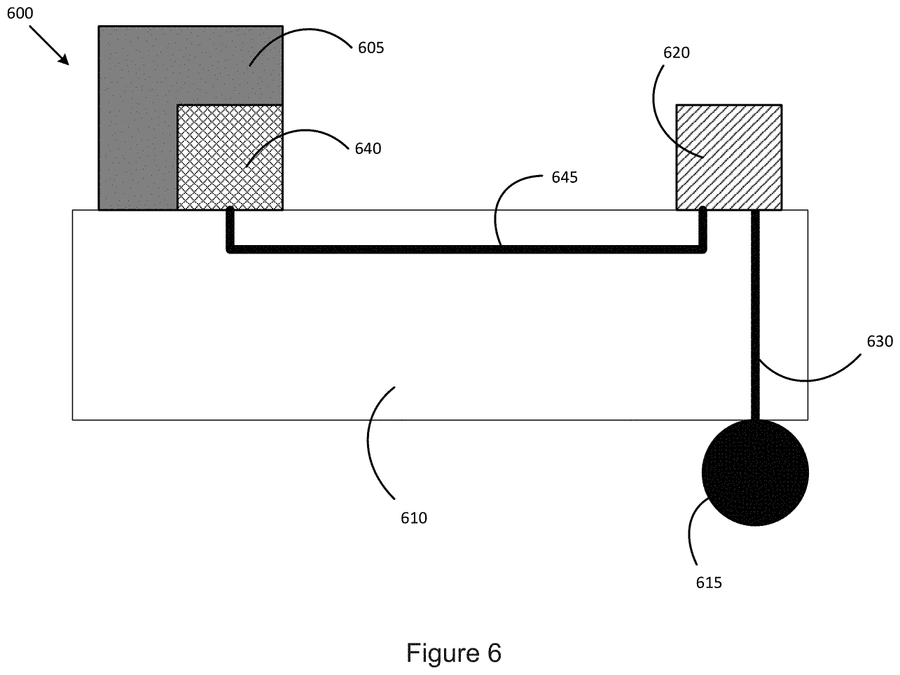

FIG. 6 depicts a simplified cross-sectional view of an example microelectronic package 600 with a reduced through-substrate signal routing pathway, in accordance with various embodiments. The microelectronic package 600 may include an active die 605, an HSIO die 620, HDP routing 645, a package substrate 610, an interconnect 615, and a through-substrate routing path 630 which may be respectively similar to, and share one or more characteristics with, active die 205, HSIO die 220, HDP routing 545, package substrate 210, interconnect 215, and through-substrate routing path 230.

The microelectronic package 600 may further include active circuitry 640. Rather than being a separate element such as an active die like active die 540 or 440, the active circuitry 640 may be implemented as circuitry within the active die 605. Specifically, the active circuitry 640 may be or include circuitry that is configured to reduce or otherwise mitigate the signal loss of the signal path between the active die 605 and the HSIO die 620. The active circuitry 640 may be or include, for example, related to a SERDES or some other type of active circuitry.

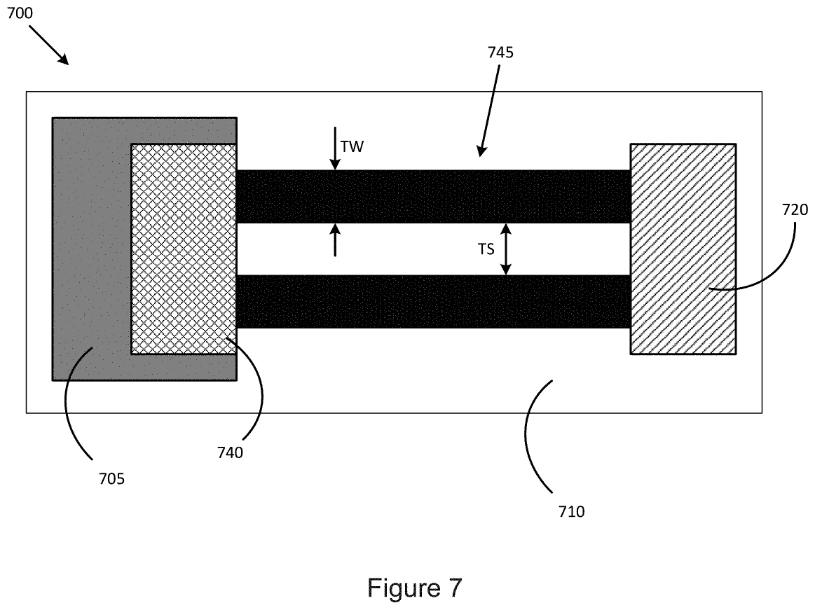

FIG. 7 depicts a simplified top-down view of an example microelectronic package 700 with a reduced through-substrate signal routing pathway, in accordance with various embodiments. Similarly to other embodiments, the specific number, shape, or relative sizes of various elements should not be viewed as limiting unless otherwise explicitly stated to be so. Additionally, similarly to other Figures herein, it will be understood that FIG. 7 is a highly simplified depiction of an example embodiment, and real-world embodiments may include more or fewer elements, or additional elements such as additional active, passive, or conductive elements. It will also be noted that FIG. 7 is not intended to be taken across a specific cross-sectional line of another embodiment such as FIG. 6, rather FIG. 7 is depicting different elements that may exist in different planes for the purpose of showing example positioning of certain elements.

The microelectronic package 700 may include an active die 705, a package substrate 710, an HSIO die 720, active circuitry 740, and HDP routing 745 which may be respectively similar to, and share one or more characteristics with, active die 205, package substrate 210, HSIO die 220, active circuitry 640, and HDP routing 545. As may be seen in FIG. 7, individual traces of the HDP routing 745 may have a trace width TW. As noted above, the trace width TW may be on the order of approximately 5 microns or less. For example, in some embodiments, the trace width TW may be between approximately 2 microns and approximately 5 microns. Similarly, individual traces of the HDP routing 745 may have a trace spacing TS. The trace spacing TS may also be on the order of approximately 5 microns or less. For example, in some embodiments, the trace spacing TS may be between approximately 2 microns and approximately 5 microns.

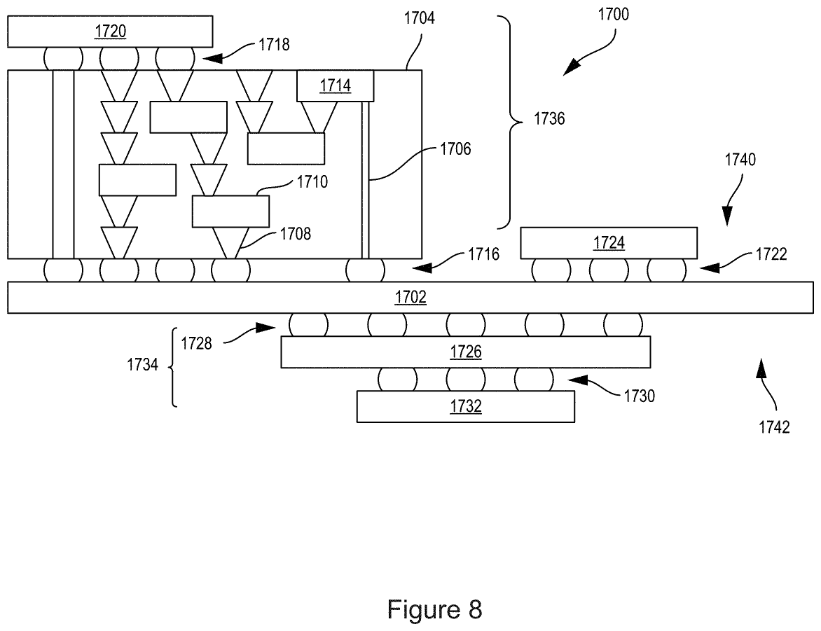

FIG. 8 is a side, cross-sectional view of an IC device assembly 1700 that may include one or more IC packages or other electronic components (e.g., a die) including one or more microelectronic packages with a reduced through-substrate signal routing pathway, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die, an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 8, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more microelectronic packages with a reduced through-substrate signal routing pathway.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

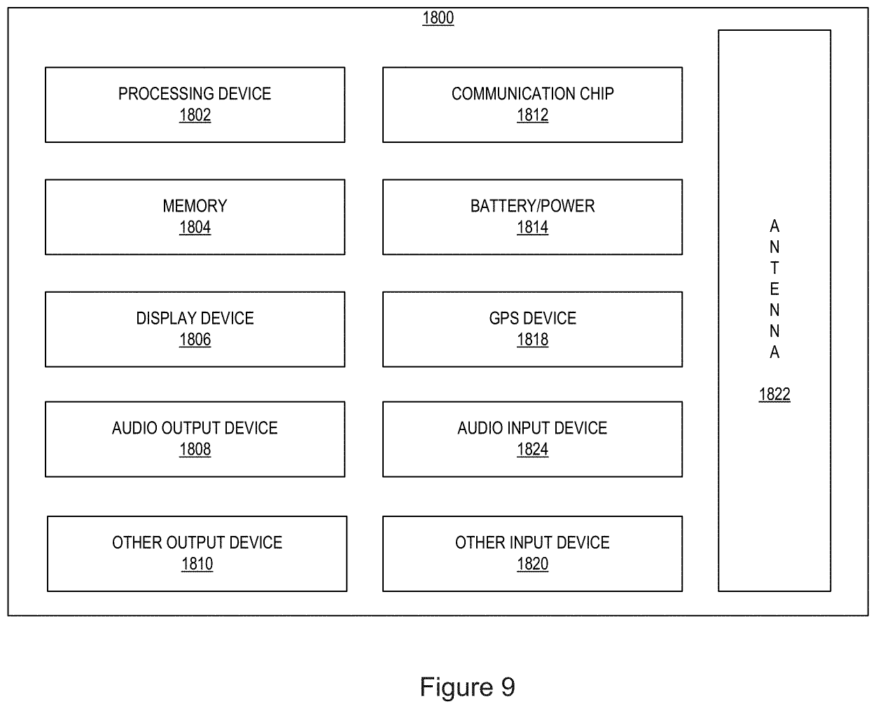

FIG. 9 is a block diagram of an example electrical device 1800 that may include one or more microelectronic packages with a reduced through-substrate signal routing pathway, in accordance with any of the embodiments disclosed herein. For example, any suitable ones of the components of the electrical device 1800 may include one or more of the IC device assemblies 1700, IC packages, IC devices, or dies disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), CPUs, GPUs, cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., ROM), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

### Examples of Various Embodiments

Example 1 includes a microelectronic package comprising: a substrate with a first side and a second side opposite the first side; an interconnect coupled with the second side of the substrate; an active die coupled with the first side of the substrate; a HSIO die coupled with the first side of the substrate; a through-substrate path that communicatively couples the HSIO die with the interconnect; and a bridge that communicatively couples the active die with the HSIO die.

Example 2 includes the microelectronic package of example 1, wherein the bridge is an active bridge with an element that is to affect a signal as it propagates through the bridge between the active die and the HSIO die.

Example 3 includes the microelectronic package of example 1, wherein the bridge is in a signal path between the active die and the HSIO die, and wherein the signal path includes a second active die coupled with the first side of the substrate.

Example 4 includes the microelectronic package of example 3, wherein the second active die is a repeater.

Example 5 includes the microelectronic package of example 3, wherein the second active die is a serializer/deserializer (SERDES).

Example 6 includes the microelectronic package of example 3, wherein the bridge communicatively couples the active die and the second active die, and wherein the microelectronic package further comprises a second bridge that communicatively couples the second active die and the HSIO die.

Example 7 includes the microelectronic package of any of examples 1-6, wherein the through-substrate path has a routing length of less than 10 mm.

Example 8 includes a microelectronic package comprising: a package substrate with a first side and a second side opposite the first side; an active die and a HSIO die coupled with the first side of the package substrate; an interconnect coupled with the second side of the package substrate, wherein the interconnect is communicatively coupled with the HSIO die by a through-substrate routing path; and an active bridge that communicatively couples the active die and the HSIO die.

Example 9 includes the microelectronic package of example 8, wherein the package substrate has a length of less than or equal to 60 mm and a width of less than or equal to 60 mm.

Example 10 includes the microelectronic package of example 8, wherein through-substrate routing path has a routing length of less than or equal to 10 mm.

Example 11 includes the microelectronic package of example 8, wherein the interconnect is an interconnect of a BGA with a 1 mm pitch.

Example 12 includes the microelectronic package of any of examples 8-11, wherein the active bridge is at least partially within the package substrate.

Example 13 includes the microelectronic package of any of examples 8-11, wherein the active bridge is an EMIB.

Example 14 includes an electronic device comprising: a PCB; a microelectronic package coupled with the PCB by an interconnect of a BGA or LGA, wherein the interconnect is coupled with a second side of a package substrate of the microelectronic package, wherein the microelectronic package further includes: an active die coupled with a first side of the package substrate that is opposite the second side; and a HSIO die coupled with the first side of the package substrate; wherein the HSIO die is communicatively coupled with the interconnect by a through-substrate signal path with a routing length of less than 10 mm; and wherein the active die and the HSIO die are communicatively coupled by a signal path that includes a serializer/deserializer (SERDES).

Example 15 includes the electronic device of example 14, wherein the signal path further includes a bridge that communicatively couple the active die and the HSIO die.

Example 16 includes the electronic device of example 15, wherein the bridge is an EMIB.

Example 17 includes the electronic device of example 14, wherein the signal path further includes fine-line traces that communicatively couple the active die and the HSIO die.

Example 18 includes the electronic device of example 17, wherein the fine-line traces have a width and spacing of less than 5 micrometers (“microns”).

Example 19 includes the electronic device of any of examples 14-18, wherein the SERDES is a die that is coupled with the first side of the package substrate.

Example 20 includes the electronic device of any of examples 14-18, wherein the SERDES is an element of the active die.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A microelectronic package comprising:
a substrate with a first side and a second side opposite the first side;
an interconnect coupled with the second side of the substrate;
an active die coupled with the first side of the substrate;
a high-speed input/output (HSIO) die coupled with the first side of the substrate;
a through-substrate path that communicatively couples the HSIO die with the interconnect; and
a bridge that communicatively couples the active die with the HSIO die.

2. The microelectronic package of claim 1, wherein the bridge is an active bridge with an element that is to affect a signal as it propagates through the bridge between the active die and the HSIO die.

3. The microelectronic package of claim 1, wherein the bridge is in a signal path between the active die and the HSIO die, and wherein the signal path includes a second active die coupled with the first side of the substrate.

4. The microelectronic package of claim 3, wherein the second active die is a repeater.

5. The microelectronic package of claim 3, wherein the second active die is a serializer/deserializer (SERDES).

6. The microelectronic package of claim 3, wherein the bridge communicatively couples the active die and the second active die, and wherein the microelectronic package further comprises a second bridge that communicatively couples the second active die and the HSIO die.

7. The microelectronic package of claim 1, wherein the through-substrate path has a routing length of less than 10 millimeters (mm).

8. A microelectronic package comprising:
a package substrate with a first side and a second side opposite the first side;
an active die and a high-speed input/output (HSIO) die coupled with the first side of the package substrate;
an interconnect coupled with the second side of the package substrate, wherein the interconnect is communicatively coupled with the HSIO die by a through-substrate routing path; and
an active bridge that communicatively couples the active die and the HSIO die.

9. The microelectronic package of claim 8, wherein the package substrate has a length of less than or equal to 60 millimeters (mm) and a width of less than or equal to 60 mm.

10. The microelectronic package of claim 8, wherein through-substrate routing path has a routing length of less than or equal to 10 millimeters (mm).

11. The microelectronic package of claim 8, wherein the interconnect is an interconnect of a ball grid array (BGA) with a 1 millimeter (mm) pitch.

12. The microelectronic package of claim 8, wherein the active bridge is at least partially within the package substrate.

13. The microelectronic package of claim 8, wherein the active bridge is an embedded multi-die interconnect bridge (EMIB).

14. An electronic device comprising:
a printed circuit board (PCB);
a microelectronic package coupled with the PCB by an interconnect of a ball grid array (BGA) or land grid array (LGA), wherein the interconnect is coupled with a second side of a package substrate of the microelectronic package, wherein the microelectronic package further includes:
an active die coupled with a first side of the package substrate that is opposite the second side; and
a high-speed input/output (HSIO) die coupled with the first side of the package substrate;
wherein the HSIO die is communicatively coupled with the interconnect by a through-substrate signal path with a routing length of less than 10 millimeters (mm); and
wherein the active die and the HSIO die are communicatively coupled by a signal path that includes a serializer/deserializer (SERDES).

15. The electronic device of claim 14, wherein the signal path further includes a bridge that communicatively couple the active die and the HSIO die.

16. The electronic device of claim 15, wherein the bridge is an embedded multi-die interconnect bridge (EMIB).

17. The electronic device of claim 14, wherein the signal path further includes fine-line traces that communicatively couple the active die and the HSIO die.

18. The electronic device of claim 17, wherein the fine-line traces have a width and spacing of less than 5 micrometers (“microns”).

19. The electronic device of claim 14, wherein the SERDES is a die that is coupled with the first side of the package substrate.

20. The electronic device of claim 14, wherein the SERDES is an element of the active die.
